(19) United States
(12) Patent Application Publication
(10) Pub. No.: US 2014/0213023 A1
(43) Pub. Date: Jul. 31, 2014

(54) METHOD FOR FABRICATING POWER SEMICONDUCTOR DEVICE

(71) Applicant: ANPEC ELECTRONICS CORPORATION, Hsin-Chu (TW)

(72) Inventor: Yung-Fa Lin, Hsinchu City (TW)

(73) Assignee: Anpec Electronics Corporation, Hsin-Chu (TW)

(21) Appl. No.: 13/783,399

(22) Filed: Mar. 4, 2013

(30) Foreign Application Priority Data
Jan. 25, 2013 (TW) 102102915

(51) Int. Cl. H01L 29/66

(52) U.S. Cl. CPC H01L 29/66477
USPC 438/197

(57) ABSTRACT

A method for fabricating a power semiconductor device is disclosed. A substrate having thereon a plurality of die regions and scribe lanes is provided. A first epitaxial layer is formed on the substrate. A hard mask is formed on the first epitaxial layer. A trench is etched into the first epitaxial layer through an opening in the hard mask. The opening and the trench both traverse the die regions and scribe lanes in their longitudinal direction. The hard mask is then removed. A second epitaxial layer is formed in the trench. After polishing the second epitaxial layer, a third epitaxial layer is formed to cover the first and second epitaxial layers.

### BACKGROUND OF THE INVENTION

1. Field of the Invention

The present invention relates generally to the field of semiconductor technology. More particularly, the present invention relates to a method for fabricating a power semiconductor device with super junction structure.

2. Description of the Prior Art

As known in the art, super junction power MOSFET devices include alternating p-type and n-type regions below the active regions of the device. The alternating p-type and n-type regions in a super junction power MOSFET device are ideally in charge balance so that those regions deplete one another under a reverse voltage condition, thereby enabling the device to better withstand breakdown.

It is known to utilize super junction structures in trench type power devices. To form such trench type super junction power devices, typically, deep trenches are etched into a main surface of a semiconductor substrate, and an epitaxial layer is then formed to fill the deep trenches. However, the prior art fabrication method has drawbacks. For example, it is difficult to control the etching profile of the deep trenches as well as the defects formed in the subsequent epitaxial growing process.

There is a need for improved methods of fabrication that can provide improved performance of the power devices.

### SUMMARY OF THE INVENTION

It is therefore one object of the present invention to provide an improved fabrication method to form trench type power semiconductor devices in order to solve the above-mentioned overlay problems.

It is another object of the present invention to provide an improved fabrication method to form a substrate that can be used to fabricate power devices thereon.

According to an embodiment, a method for fabricating a power semiconductor device is disclosed. A substrate having thereon a plurality of die regions and scribe lanes between the die regions is provided. A first epitaxial layer is formed on the substrate. A hard mask is formed on the first epitaxial layer. A line-shaped trench is etched into the first epitaxial layer through an opening in the hard mask. The opening and the trench both traverse the die regions and scribe lanes in their longitudinal direction. The hard mask is then removed. A second epitaxial layer is formed in the trench. After polishing the second epitaxial layer, a third epitaxial layer is formed to cover the first and second epitaxial layers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIGS. 1-8 are schematic diagrams illustrating a method for fabricating a trench type power transistor device in accordance with one embodiment of the invention, wherein FIG. 2 shows an exemplary wafer and an array of die regions thereon; and

FIG. 9 shows a grid type trench pattern.

It should be noted that all the figures are diagrammatic. Relative dimensions and proportions of parts of the drawings are exaggerated or reduced in size, for the sake of clarity and convenience. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known process steps such as lithographic and etching processes are not disclosed in detail, as these should be well-known to those skilled in the art.

The terms wafer or substrate used herein includes any structure having an exposed surface onto which a layer may be deposited according to the present invention, for example, to form the integrated circuit (IC) structure. The term substrate is understood to include semiconductor wafers commonly used in this industry. The term substrate is also used to refer to semiconductor structures during processing, and may include other layers that have been fabricated thereupon. Both wafer and substrate may include doped and undoped semiconductors, epitaxial semiconductor layers supported by a base semiconductor or insulator, as well as other semiconductor structures well known to one skilled in the art.

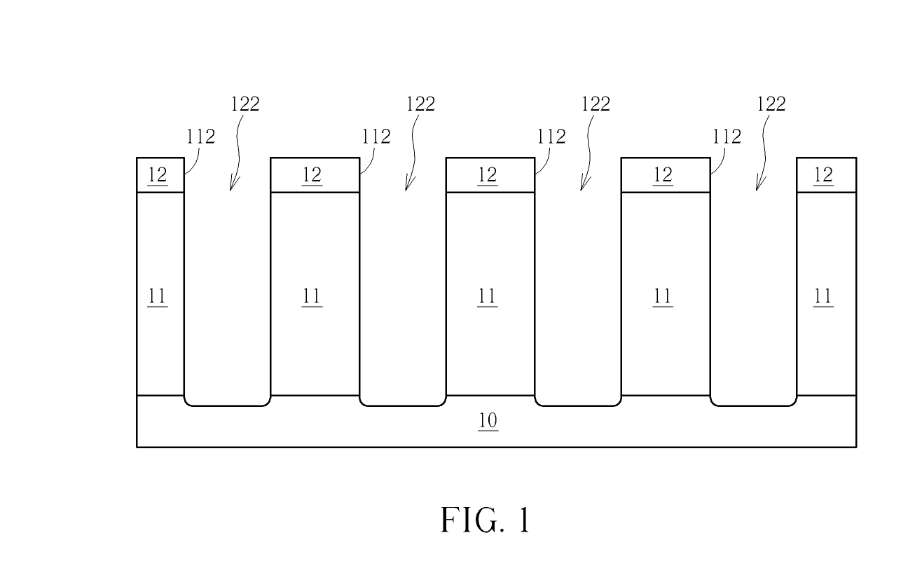

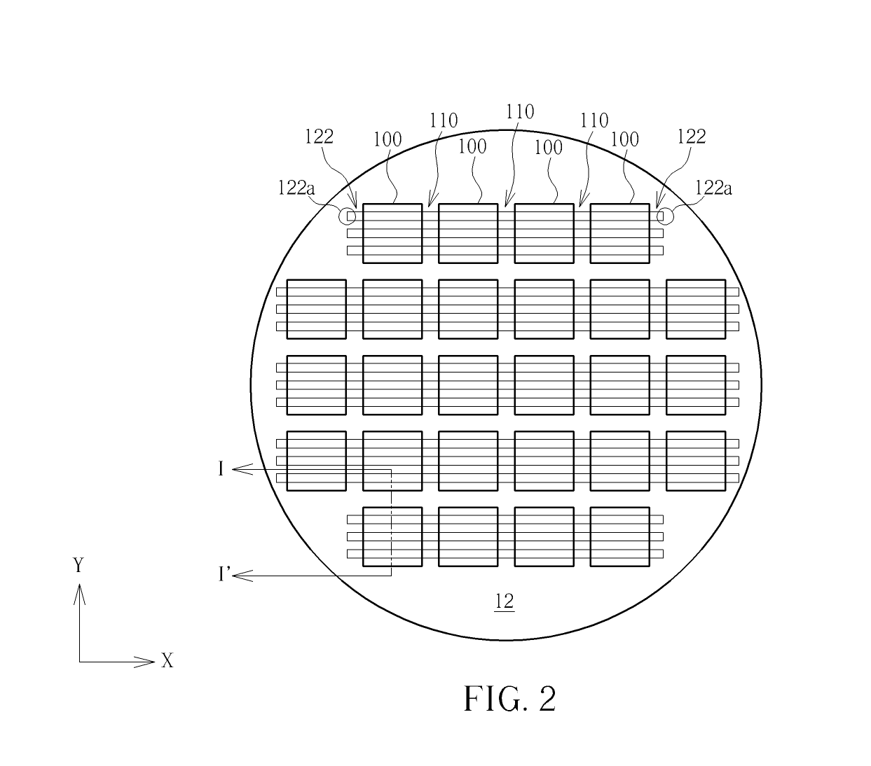

FIGS. 1-8 are schematic diagrams illustrating a method for fabricating a trench type power transistor device in accordance with one embodiment of the invention, wherein FIG. 1 is a cross-sectional view taken along line I-I′ in FIG. 2. As shown in FIG. 1 and FIG. 2, a semiconductor substrate 10 is provided. The semiconductor substrate 10 has a first conductivity type. For example, the semiconductor substrate 10 may be a heavily N type doped silicon substrate and may act as a drain of the transistor devices formed therein. On the main surface of the semiconductor substrate 10, a plurality of die regions 100 are defined by the scribe lanes 110 between the die regions 100, which can be best seen in FIG. 2. A plurality of trench type power devices are to be formed in each of the die regions 100.

Still referring to FIG. 1, an epitaxial layer 11 such as an N type epitaxial silicon layer is formed on the semiconductor substrate 10 by performing an epitaxial growth process. A hard mask 12 is then formed on the epitaxial layer 11. For example, the hard mask 12 may be a silicon oxide layer or a silicon nitride layer. Subsequently, openings 112 are formed in the hard mask 12 by using lithographic and etching processes. After removing the photoresist pattern (not shown) from the top surface of the hard mask 12, an anisotropic dry etching process is carried out to etch the epitaxial layer 11 through the openings 112 in the hard mask 12 to a predetermined depth of the epitaxial layer 11, thereby forming trenches 122. For example, the trenches 122 are line shaped and are in parallel to one another.

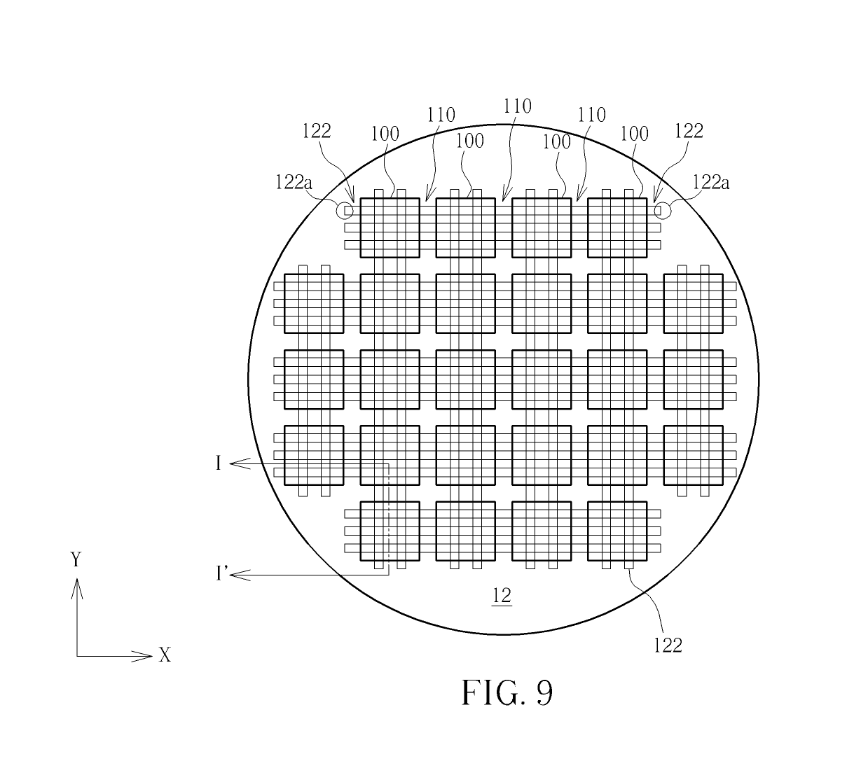

As shown in FIG. 2, it is one germane feature of the invention that the aforesaid openings 112 and the trenches 122 both traverse the plural die regions 100 and the scribe lanes 110 such that the two distal ends 122a of each of the trenches 122 are not located within any die region 100. That is, the two distal ends 122a do not overlap with the die regions 100. According to the embodiment, each line-shaped trench 122 is continuous along its extending direction (e.g., the reference x-axis) and traverses the multiple die regions 100 in the same row along that direction. Alternatively, as shown in FIG. 9, the trenches 122 may be in a grid pattern. The line-shaped trenches 122 extending along two different directions (e.g., reference x-axis and y-axis) are continuous and intersect one another. Likewise, all of the line-shaped trenches traverse the plural die regions 100 such that the two distal ends 122a of each of the trenches 122 are not located within any die region 100.

By locating the two distal ends 122a of each of the trenches 122 at the perimeter of the array of the die regions 100 or on the outskirt of the wafer, the interfacial defects usually generated at the two ends 122a of the trench 122 during the epitaxial growth process can be reduced, particularly in the die regions 100. Therefore, the performance of the power devices formed within the die regions 100 can be improved. It is to be understood that the dimension and quantity of the die regions 100, and the amount and shape of the trenches 122 as depicted in FIG. 2 are only for illustration purposes, and should not limit the scope of the invention.

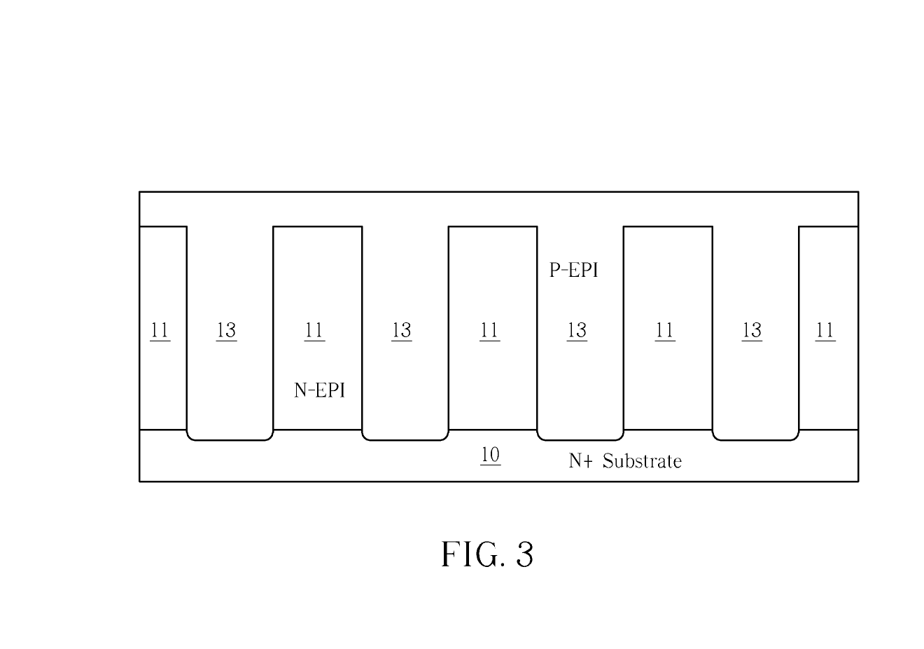

As shown in FIG. 3, the hard mask 12 is removed. An epitaxial growth process is performed to fill the trenches 122 with an epitaxial layer 13 having a second conductivity type, for example, a P type epitaxial silicon layer (P-EPI). According to the embodiment, the epitaxial layers 11 and 13 have opposite conductivity types. According to the embodiment, the epitaxial layer 13 may cover the epitaxial layer 11.

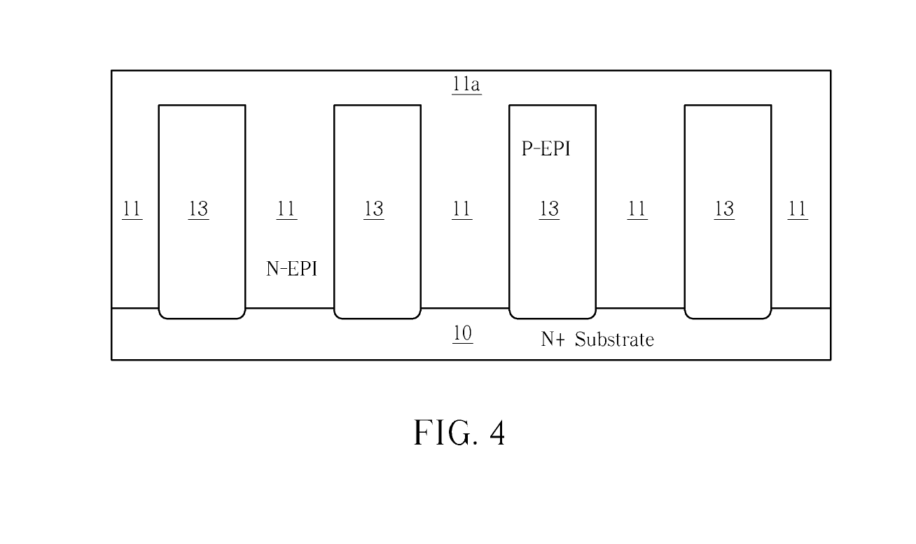

Subsequently, as shown in FIG. 4, a chemical mechanical polishing (CMP) process is performed to remove a portion of the epitaxial layer 13, thereby revealing the top surface of the epitaxial layer 11 and forming a substantially planar surface. An additional epitaxial growth process is then performed to form an epitaxial layer 11 a having the first conductivity type. The epitaxial layer 11a covers the epitaxial layers 11 and 13. According to the embodiment, the epitaxial layer 11 a and the epitaxial layer 11 have the same conductivity type, while the epitaxial layer 11 a and the epitaxial layer 13 have opposite conductivity types. According to the embodiment, the epitaxial layer 11 a is an N type epitaxial silicon layer (N-EPI). The semiconductor substrate 10, the epitaxial layer 11, the epitaxial layer 13 embedded in the trenches 122, and the epitaxial layer 11 a capping the epitaxial layer 11 and the epitaxial layer 13 constitute a substrate material for fabricating power devices with super junction structures.

In addition to the steps as disclosed in FIGS. 1-4, according to another embodiment, a first (P type) epitaxial layer 11 may be first formed on the N type semiconductor substrate 10. After etching the trenches 122 and filling the trenches with a second (N type) epitaxial layer 13, the N type region (similar to 11 a) overlying the first (P type) epitaxial layer 11 may be retained, or alternatively polished to the first (P type) epitaxial layer, then covered with a third (N type) epitaxial layer.

It is noteworthy that when the epitaxial layer 11 is N type, the aforesaid trenches 122 has a depth that can be deeper or not deeper than the entire thickness of the epitaxial layer 11, and when the epitaxial layer 11 is P type, the depth of the aforesaid trenches 122 has to be deeper than the entire thickness of the epitaxial layer 11.

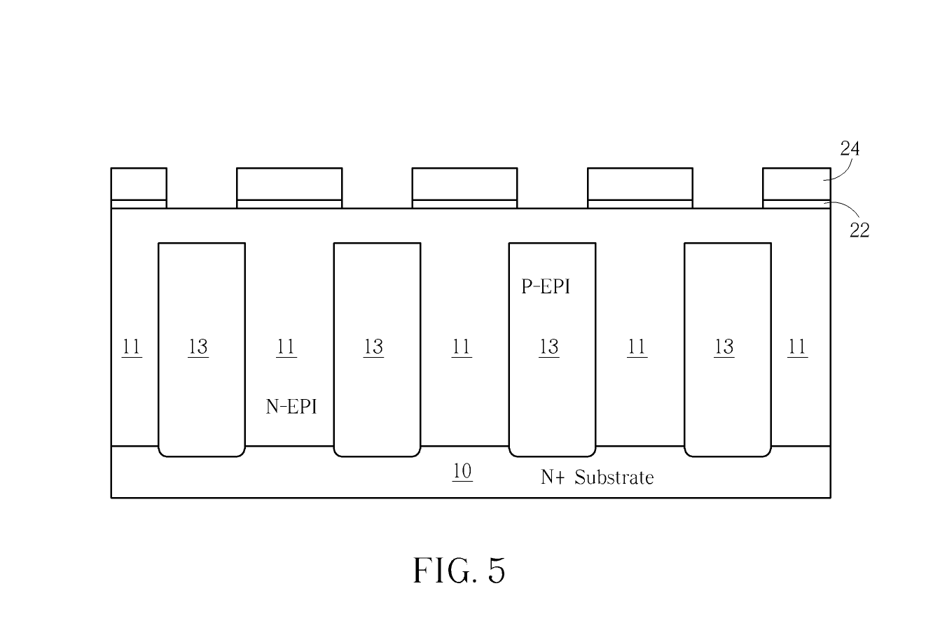

As shown in FIG. 5, gate oxide layer 22 and gates 24 are formed on the epitaxial layer 11 a. According to the embodiment, the gates 24 may be polysilicon gates. According to the embodiment, the gates 24 may be line-shaped gates. To pattern the gates 24 within the die regions 100, lithographic and etching processes are performed.

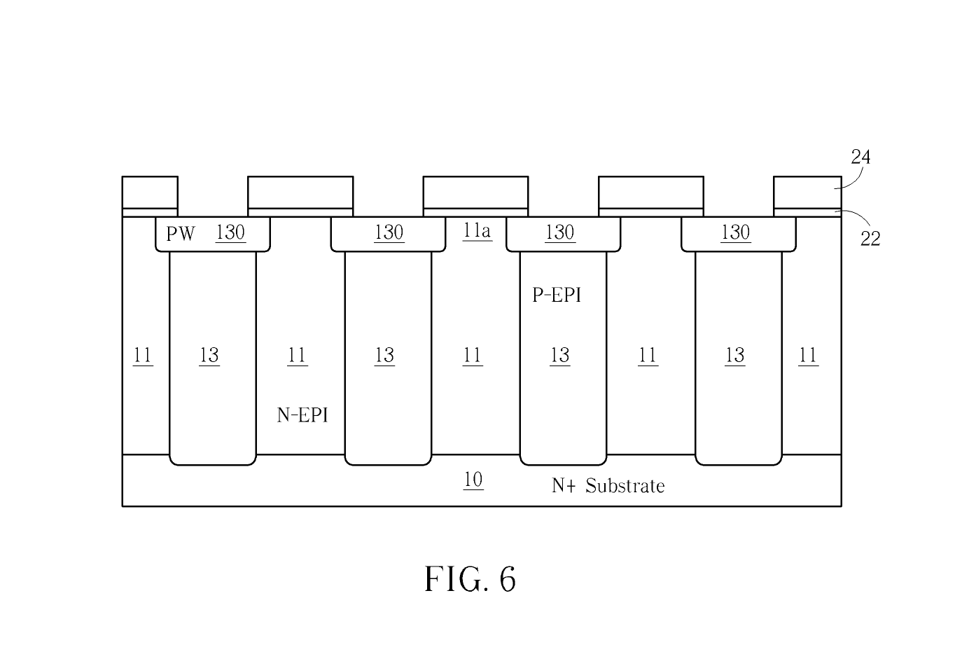

As shown in FIG. 6, an ion implantation process is carried out to implant dopants of second conductivity type such as P type into the epitaxial layer 11 a between the gates 24, thereby forming ion well 130 such as P well (PW). Optionally, a thermal drive-in process may be performed.

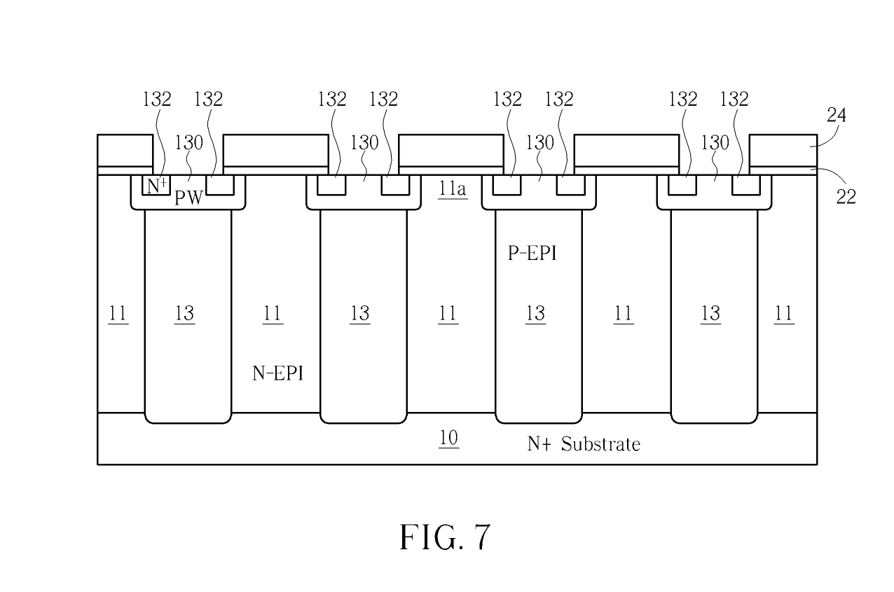

As shown in FIG. 7, lithographic and etching processes are performed to define the source regions. Subsequently, an ion implantation process is carried out to implant dopants of first conductivity type such as N type into the ion well 130, thereby forming N+source doping regions 132. Optionally, a thermal drive-in process may be performed.

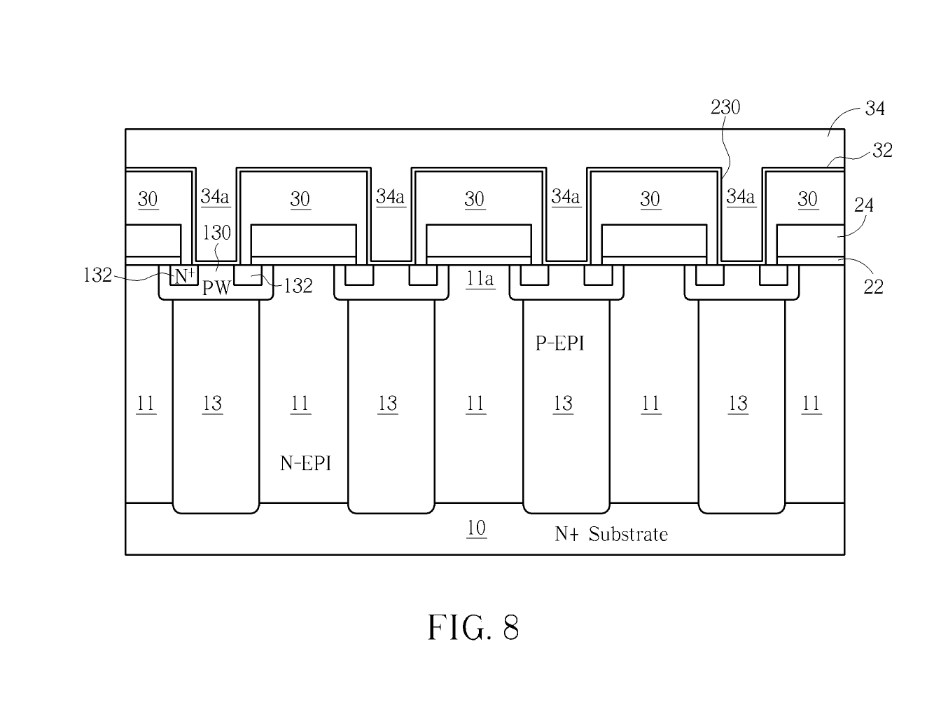

As shown in FIG. 8, contact holes are formed and metalized. To form the metalized contact holes, an inter-layer dielectric (ILD) layer 30 is first deposited. Then contact holes 230 are formed in the ILD layer 30. Barrier layer 32 and metal layer 34 are deposited to fill the contact holes 230, thereby forming the contact elements 34a in contact with the ion well 130 and the source doping regions 132.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating a power semiconductor device, comprising:
providing a semiconductor wafer of a first conductivity type having thereon a plurality of die regions and scribe lanes between the die regions;
forming a first epitaxial layer of the first conductivity type on the semiconductor wafer;
forming a hard mask on the first epitaxial layer;
forming at least an opening in the hard mask;
etching the first epitaxial layer through the opening to form at least one trench, wherein the opening and the trench traverse the plurality of die regions and the scribe lanes such that two distal ends of the trench are not located with any of the die regions, and wherein no discontinuity is formed along an extending direction of the trench between the two distal ends that are both ended up within an outer circumferential region of the semiconductor wafer;
removing the hard mask;
filling the trench with a second epitaxial layer of the second conductivity type, wherein the second epitaxial layer covers the first epitaxial layer;
performing a chemical mechanical polishing (CMP) process to remove a portion of the second epitaxial layer, thereby revealing the first epitaxial layer; and
forming a third epitaxial layer of the first conductivity type on the first and second epitaxial layers.

2. The method for fabricating a power semiconductor device according to claim 1 wherein the first conductivity type is N type and the second conductivity type is P type.

3. The method for fabricating a power semiconductor device according to claim 1 wherein the first, second, and third epitaxial layers are epitaxial silicon layers.

4. The method for fabricating a power semiconductor device according to claim 1 wherein after forming the third epitaxial layer, the method further comprises:
forming a gate oxide layer and gates on the third epitaxial layer;
performing an ion implantation process to implant dopants of the second conductivity type into the third epitaxial layer between the gates, thereby forming an ion well; and
forming a source doping region in the ion well.

5. The method for fabricating a power semiconductor device according to claim 4 wherein after forming the source doping region, the method further comprises:
forming an inter-layer dielectric (ILD) layer;
forming at least one contact hole in the ILD layer; and
depositing a barrier layer and a metal layer to fill the contact hole, thereby forming a contact element.

6. The method for fabricating a power semiconductor device according to claim 1 wherein the semiconductor wafer acts as a drain of the power semiconductor device.

7. A method for fabricating a power semiconductor device, comprising:
providing a semiconductor wafer of a first conductivity type having thereon a plurality of die regions and scribe lanes between the die regions;
forming a first epitaxial layer of a second conductivity type on the semiconductor wafer;
forming a hard mask on the first epitaxial layer;
forming at least an opening in the hard mask;
etching the first epitaxial layer through the opening to form at least one trench, wherein the opening and the trench traverse the die regions and the scribe lanes such that two distal ends of the trench are not located with any of the die regions, and wherein no discontinuity is formed along an extending direction of the trench between the two distal ends that are both ended up within an outer circumferential region of the semiconductor wafer;
removing the hard mask; and
filling the trench with a second epitaxial layer of the first conductivity type, wherein the second epitaxial layer covers the first epitaxial layer.

8. (canceled)

9. The method for fabricating a power semiconductor device according to claim 7 wherein the first conductivity type is N type and the second conductivity type is P type.
